(19) United States
(12) Patent Application Publication
(10) Pub. No.: US 2024/0170327 A1
(43) Pub. Date: May 23, 2024

(54) SEMICONDUCTOR DEVICE INCLUDING HYDROGEN INTRODUCTION LAYER PROVIDED ON SEMICONDUCTOR SUBSTRATE AND METHOD OF FORMING THE SAME

(71) Applicant: Micron Technology, Inc., Boise, ID (US)

(72) Inventors: MITSUNARI SUKEKAWA, Hiroshima-shi (JP); HIDEKAZU GOTO, Higashihiroshima (JP); SHINICHI NAKATA, Higashihiroshima (JP)

(73) Assignee: Micron Technology, Inc., Boise, ID (US)

(21) Appl. No.: 18/461,086

(22) Filed: Sep. 5, 2023

Related U.S. Application Data
(60) Provisional application No. 63/384,708, filed on Nov. 22, 2022.

(51) Int. Cl. H01L 21/762; H01L 27/088; H10B 12/00

(52) U.S. Cl. CPC H01L 21/76254; H01L 21/76224; H01L 27/088; H10B 12/30

(57) ABSTRACT

An apparatus includes: a first semiconductor substrate; a plurality of first regions extending in parallel in a first direction on the first semiconductor substrate, each of the plurality of first regions including a plurality of first shallow trench isolations (STI) therein; and a plurality of second regions each extending between corresponding adjacent two of the plurality of first regions, each of the plurality of second regions including a plurality of second STIs and a plurality of active regions arranged alternately and in line in the first direction. Each of the plurality of second STIs has a greater depth than each of the plurality of first STIs.

### CROSS REFERENCE TO RELATED APPLICATION(S)

This application claims priority to U.S. Provisional Application No. 63/384,708, filed Nov. 22, 2022. The aforementioned application is incorporated herein by reference, in its entirety, for any purpose.

### BACKGROUND

In recent years, semiconductor devices exemplified by dynamic random access memories (DRAMs) have been desired to have increased memory capacity. However, it is technically difficult to increase the memory capacity by fining processing dimensions. Therefore, there has been developed a technique which reduces the planar area of a memory cell by vertically stacking an access transistor and a storage capacitor of the memory cell to increase the memory capacity.

For example, a technique of forming an access transistor, a storage capacitor, and peripheral transistors of a memory cell on separate semiconductor substrates, and then bonding these substrates together to form DRAM has been developed as a technique for vertically stacking an access transistor and a storage capacitor of a DRAM memory cell.

### BRIEF DESCRIPTION OF THE DRAWINGS

FIG. 1A is a plan view showing a schematic configuration of a part of a semiconductor device according to a first embodiment.

FIG. 1B and FIGS. 2 to 5 are diagrams showing a method of manufacturing the semiconductor device according to the first embodiment, and are longitudinal sectional views showing a schematic configuration of the semiconductor device in exemplary process stages, and also FIG. 1B and FIGS. 2 to 5 are longitudinal sectional views schematically showing a portion taken along line A-A in FIG. 1A.

FIG. 6A is a diagram showing the method of manufacturing the semiconductor device according to the first embodiment, and is a plan view showing a schematic configuration of the semiconductor device in a process stage subsequent to FIG. 5.

FIGS. 6B, 7 and 8 are diagrams showing the method of manufacturing the semiconductor device according to the first embodiment, and are longitudinal sectional views showing a schematic configuration of the semiconductor device in a process stage subsequent to FIG. 5, and also FIGS. 6B, 7 and 8 are longitudinal sectional views schematically showing a portion taken along line A-A in FIG. 6A.

FIGS. 9A and 9B are a plan view and a longitudinal sectional view showing the method of manufacturing the semiconductor device according to the first embodiment, and are diagrams showing a schematic configuration of the semiconductor device in a process stage subsequent to FIG. 8, and FIG. 9B is a longitudinal sectional view schematically showing a portion taken along line A-A in FIG. 9A.

FIGS. 10A and 10B are a plan view and a longitudinal sectional view showing the method of manufacturing the semiconductor device according to the first embodiment, and are diagrams showing a schematic configuration of the semiconductor device in a process stage subsequent to FIGS. 9A and 9B, and FIG. 10B is a longitudinal sectional view schematically showing a portion taken along line A-A in FIG. 10A.

FIGS. 11A, 11B and 11C are a plan view and longitudinal sectional views showing the semiconductor device according to the first embodiment and the method of manufacturing the same, and are diagrams showing a schematic configuration of the semiconductor device in a process stage subsequent to FIGS. 10A and 10B, FIG. 11B is a longitudinal sectional view schematically showing a portion taken along line B-B of FIG. 11A, and FIG. 11C is a longitudinal sectional view schematically showing a portion taken along line C-C in FIG. 11A.

FIGS. 12A and 12B to FIGS. 20A and 20B are diagrams showing a schematic configuration of a semiconductor device according to a second embodiment and a method of manufacturing the same, FIGS. 12A to 20A are plan views showing a schematic configuration of the semiconductor device in exemplary process stages, FIGS. 12B to 20B are longitudinal sectional views showing a schematic configuration of a memory cell region in exemplary process stages, and FIGS. 12B to 20B are cross-sectional views showing a schematic configuration of a portion taken along line D-D in FIGS. 12A to 20A.

FIG. 21 is a circuit diagram showing a schematic configuration of an equivalent circuit of the memory cells of the semiconductor devices according to the first and second embodiments.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

Semiconductor devices according to first and second embodiments and a method of manufacturing the same will be described below with reference to the drawings. In the following description, a dynamic random access memory (hereinafter referred to as DRAM) will be illustrated as a semiconductor device. In the description of the embodiments, common or related elements or substantially the same elements are denoted by the same reference numerals, and duplicative description thereof will be omitted. In the following figures, the dimensions and dimensional ratios of the respective portions in the respective figures do not necessarily match the dimensions and dimensional ratios in the embodiments. Further, in the following description, a Y-direction is a direction perpendicular to an X-direction. A Z-direction is a direction perpendicular to an X-Y plane which is a plane of the semiconductor substrate, and may be referred to as a vertical direction.

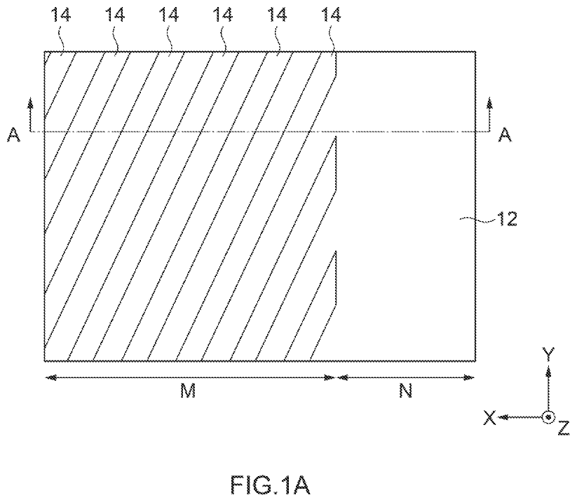

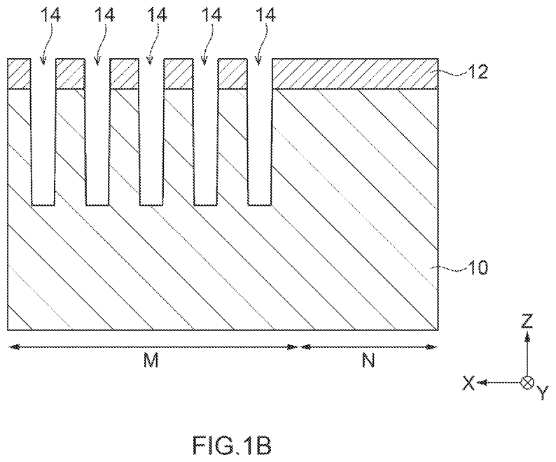

The method of manufacturing the semiconductor device according to the first embodiment will be described below. As shown in FIGS. 1A and 1B, a first insulating film 12 is formed on a semiconductor substrate 10 including a memory cell region M and a peripheral circuit region N adjacent to the memory cell region M. Next, isolation trenches 14 are formed by using a known lithography technique and an anisotropic dry etching technique. The semiconductor substrate 10 includes, for example, a disk-shaped single-crystal silicon wafer having a mirror-finished principal surface. The first insulating film 12 contains an insulating material, for example, silicon nitride (SiN). The first insulating film 12 is formed, for example, by chemical vapor deposition (CVD). A plurality of isolation trenches 14 are arranged in the memory cell region M as shown in FIG. 1A. Each isolation trench 14 has a linear shape and is obliquely arranged in plan view, and the plurality of isolation trenches 14 are arranged in parallel to one another.

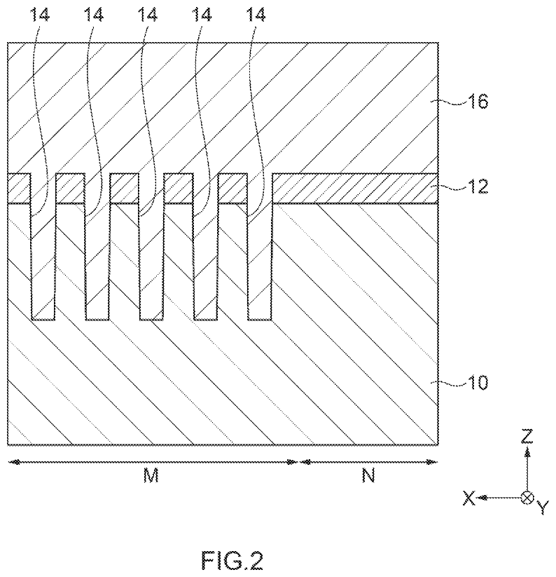

Next, as shown in FIG. 2, a second insulating film 16 is formed to fill the isolation trenches 14 and cover the surface of the first insulating film 12. The second insulating film 16 contains an insulating material, for example, silicon dioxide (SiO₂). The second insulating film 16 is formed, for example, by CVD.

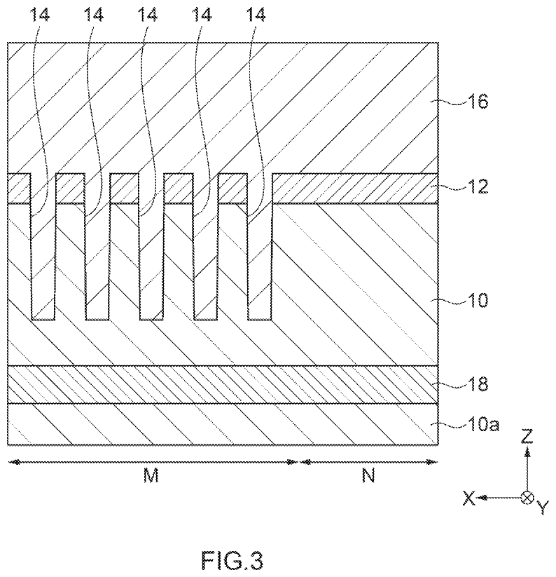

Next, as shown in FIG. 3, a hydrogen-implanted layer 18 is formed at a predetermined depth in the semiconductor substrate 10. Hydrogen (H) is introduced into the hydrogen-implanted layer 18. Hydrogen is formed, for example, by ion implantation of hydrogen ions (H⁺). The ion implantation is performed, for example, under the condition of an implantation energy of 50 Kev and an implantation dose of 1E16 atms/cm². The hydrogen-implanted layer 18 is arranged between a lower semiconductor substrate 10a and the semiconductor substrate 10 above the lower semiconductor substrate 10a. In the first embodiment, hydrogen ions are implanted into the semiconductor substrate 10 in a state where structures such as the isolation trenches 14 have been formed.

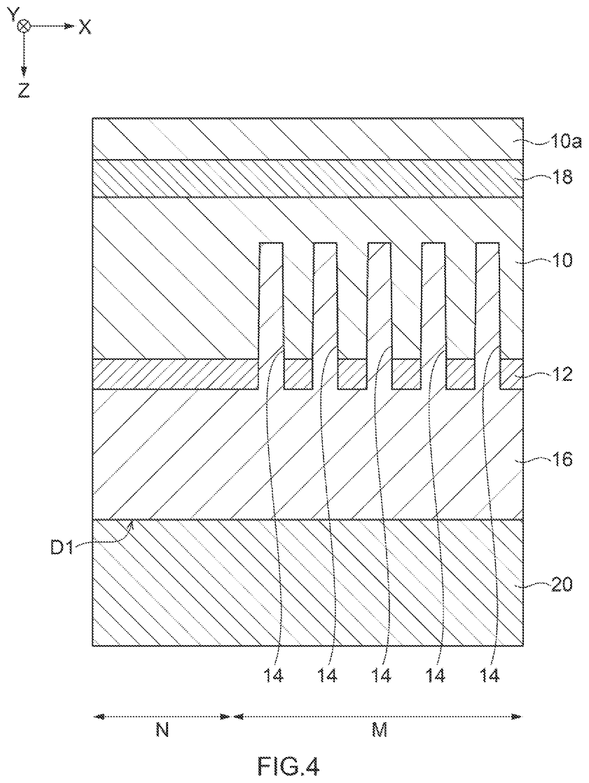

Next, as shown in FIG. 4, the semiconductor substrate 10 is rotated such that an X-axis is rotated around a Y-axis by 180 degrees. Next, by a wafer bonding technique, the semiconductor substrate 10 is bonded at a bonding surface D1 to a first support substrate 20 on which a thin insulating film has been formed in advance. The surface of the second insulating film 16 and the surface of the first support substrate 20 are in contact with each other at the bonding surface D1.

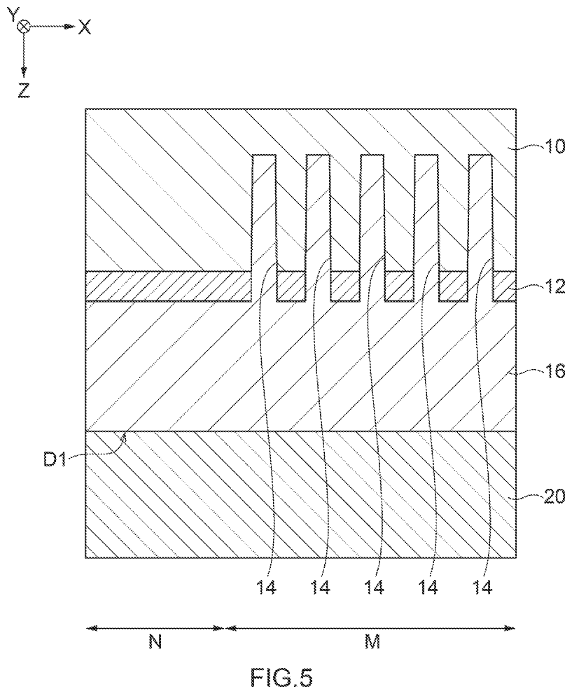

Next, as shown in FIG. 5, the semiconductor substrate 10 having the isolation trenches 14 formed therein and the first support substrate 20 bonded thereto is subjected to an annealing treatment at a temperature of 400 to 500° C. in an N2 atmosphere, for example, for 30 minutes. As a result, the hydrogen-implanted layer 18 expands, and the lower semiconductor substrate 10a is peeled off at the hydrogen-implanted layer 18. The lower semiconductor substrate 10a which is a part of the semiconductor substrate 10 is peeled off by forming the hydrogen-implanted layer 18 and performing the annealing treatment as described above, thereby thinning the semiconductor substrate 10, which is called a smart cut technique. As described above, in the first embodiment, the smart cut technique is performed on the semiconductor substrate 10 on which patterned structures such as the isolation trenches 14 are formed.

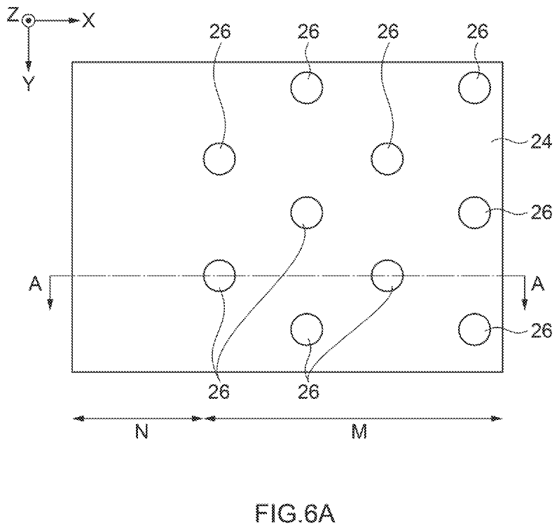

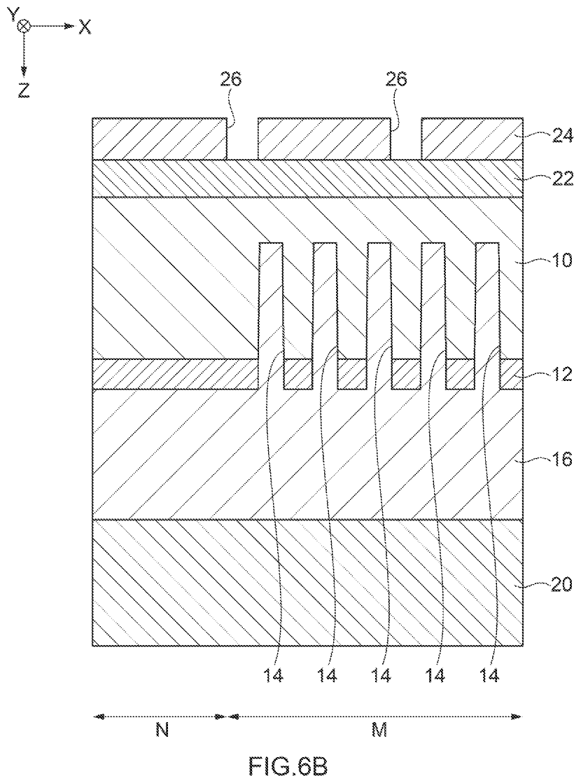

Next, as shown in FIGS. 6A and 6B, a third insulating film 22 is formed on the semiconductor substrate 10, and then a first resist 24 having openings 26 formed therein is formed. The third insulating film 22 contains an insulating material, for example silicon dioxide. The first resist 24 is formed using the known lithography technique. The openings 26 are arranged to be equally spaced from one another above and between the isolation trenches 14 located at predetermined positions.

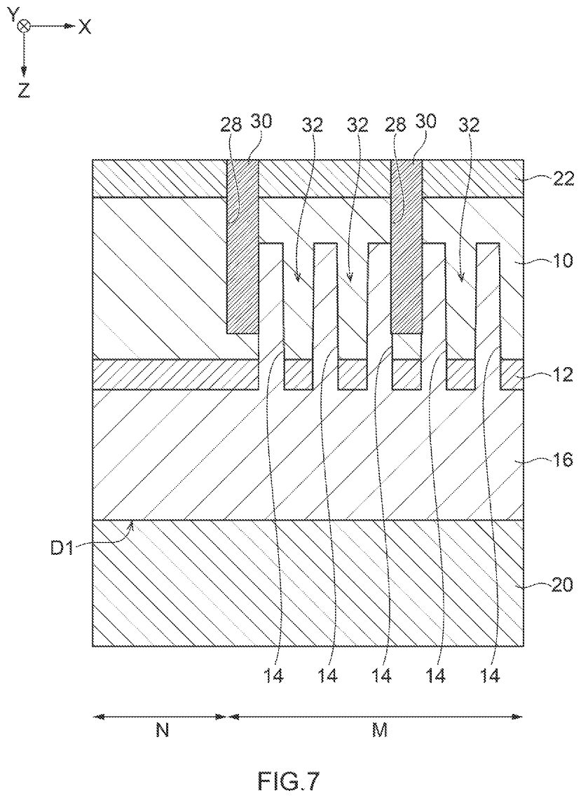

Next, anisotropic dry etching is performed using the first resist 24 as a mask. This anisotropic dry etching penetrates the third insulating film 22, and further etches a part of the semiconductor substrate 10 to form active isolation holes 28. Next, after the first resist 24 is removed, an insulating material is formed to fill the active isolation holes 28 and cover the third insulating film 22. The insulating material contains, for example, silicon dioxide. Next, etch back is performed by anisotropic dry etching to etch the insulating material, expose the upper surface of the third insulating film 22, and leave pillar-shaped active isolation insulating films 30 in the active isolation holes 28. The etch back by anisotropic dry etching is performed, for example, by setting an etching time in advance. A part of the side surface of the active isolation insulating film 30 is in contact with the side surface of the isolation trench 14. Through the above steps, the structures shown in FIG. 7 are formed. The space between the isolation trenches 14 is an active region 32 serving as an island, and the isolation trenches 14 or the active isolation insulating films 30 have a function of isolating the active regions 32. In a direction in which the active regions 32 extend, the active isolation insulating films 30 and the active regions 32 are alternately arranged in a row.

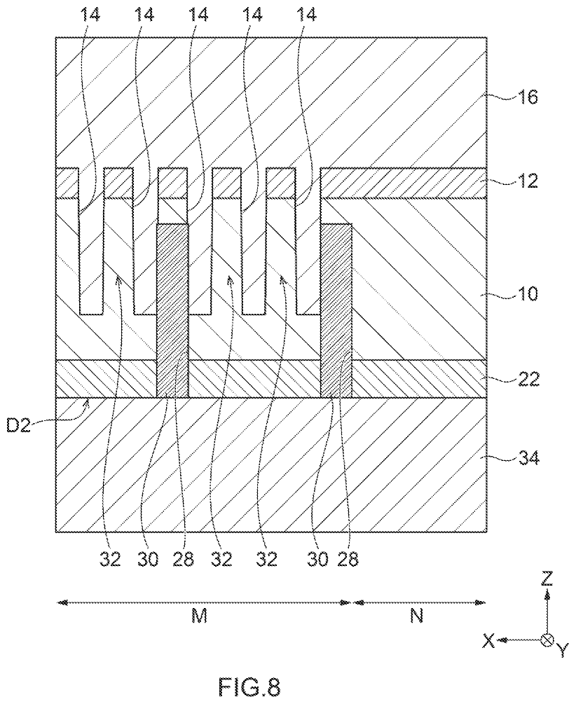

Next, as shown in FIG. 8, the semiconductor substrate 10 is rotated such that the X-axis is rotated around the Y-axis by 180 degrees. Next, by the wafer bonding technique, the semiconductor substrate 10 is bonded at a bonding surface D2 to a second support substrate 34 on which a thin insulating film has been formed in advance. The surface of the third insulating film 22 and the surface of the second support substrate 34 are in contact with each other at the bonding surface D2. Next, the first support substrate 20 is removed by etching. Anisotropic or isotropic dry etching can be used for this etching.

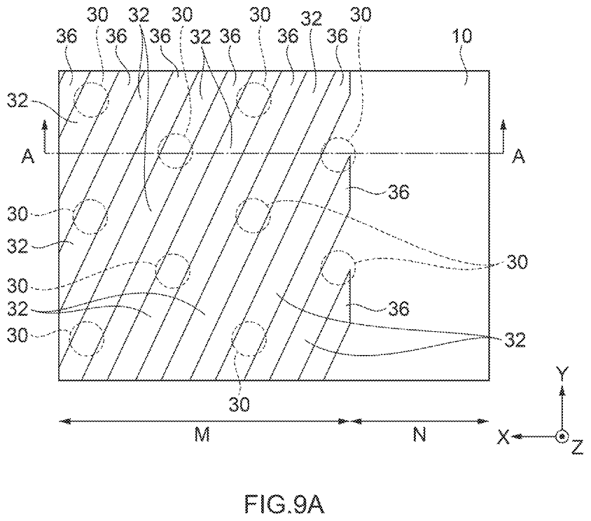

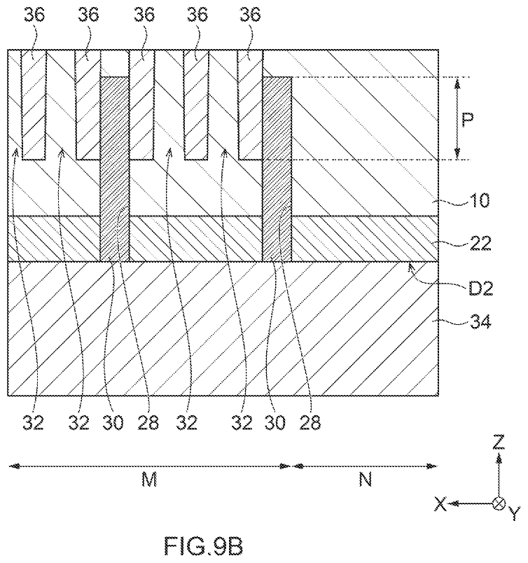

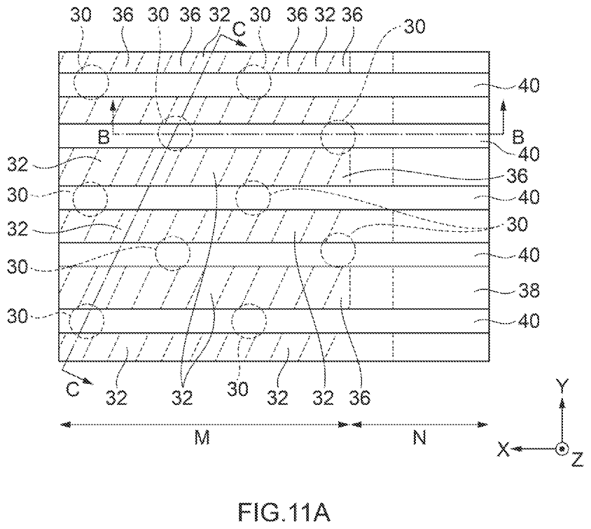

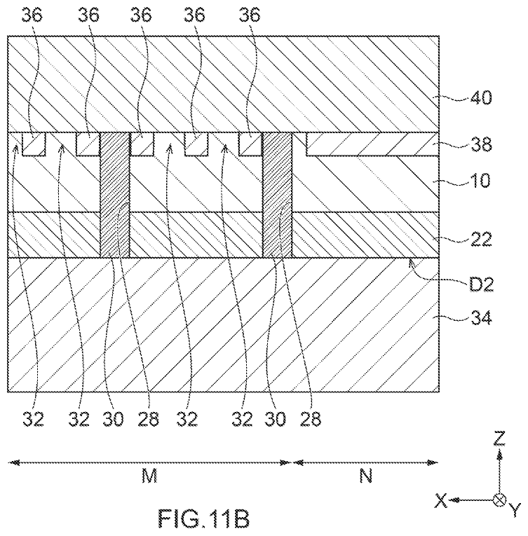

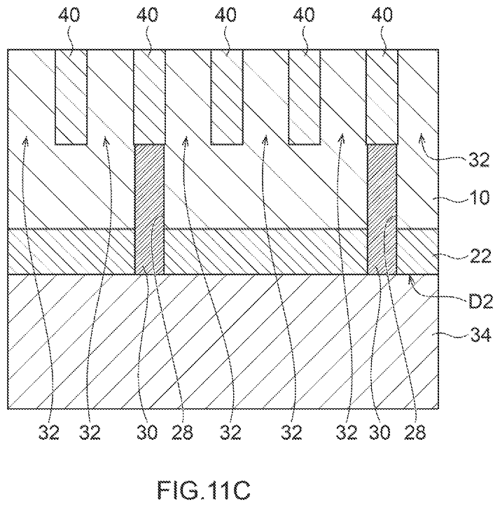

Next, as shown in FIGS. 9A and 9B, the second insulating film 16 and the first insulating film 12 are polished and removed by the CMP technique until the surface of the semiconductor substrate 10 is exposed. As a result, the second insulating film 16 remains in the isolation trenches 14, and becomes isolation insulating films 36. As shown in FIG. 9A, the active isolation insulating films 30 are arranged at predetermined intervals between adjacent isolation insulating films 36 along the isolation insulating films 36. As shown in FIGS. 9A and 9B, the side surfaces of the active isolation insulating films 30 are in contact with the isolation insulating films 36 adjacent thereto. A contact length P between the isolation insulating film 36 and the active isolation insulating film 30 is set in advance according to an etch-back amount described later with reference to FIGS. 11A, 11B and 11C.

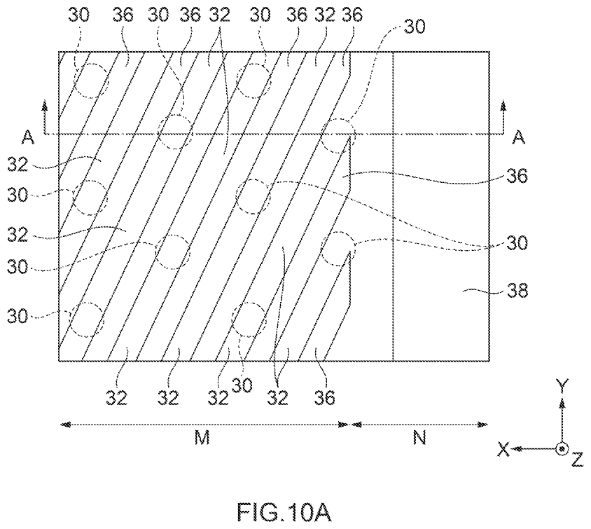

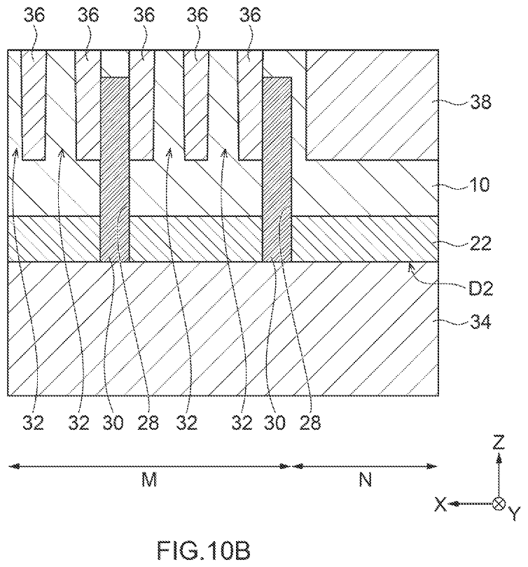

Next, a peripheral isolation 38 is formed in the peripheral circuit region N as shown in FIGS. 10A and 10B. The peripheral isolation 38 is formed by the following steps. First, a groove is formed in the peripheral circuit region N by using the known lithography technique and the anisotropic dry etching technique. Next, formation of an insulating material using a CVD technique and etch back using anisotropic dry etching are performed, whereby an insulating material is left in the groove. The peripheral isolation 38 contains an insulating material, for example contains silicon dioxide. Through the above steps, the structures shown in FIGS. 10A and 10B are formed.

Next, word-lines 40 are formed as shown in FIGS. 11A, 11B and 11C. The word-lines 40 are formed by the following steps. First, a plurality of trenches extending in parallel to the X-direction in the figure are formed. The trenches are formed using the known lithography technique and the anisotropic dry etching technique. The anisotropic dry etching is performed to the extent that at least the upper surfaces of the active isolation insulating films 30 are exposed, and parts of the active isolation insulating films 30, the isolation insulating films 36 and the peripheral isolation 38 are etched. Next, a conductive material is formed so as to fill the trenches and cover the upper surfaces of the semiconductor substrate 10, the isolation insulating films 36 and the peripheral isolation 38. The conductive material is formed, for example, by CVD. Then, etch back is performed by anisotropic dry etching so as to remove the conductive material outside the trenches and leave the conductive material in the trenches. The word-lines 40 are formed in the trenches through the above steps. The word-lines 40 include the conductive material, for example, titanium nitride. The word-line 40 is arranged so as to straddle over a plurality of active isolation insulating films 30. The bottom surface of the word-line 40 and the top surface of the active isolation insulating film 30 are in contact with each other. The active isolation insulating film 30 is sandwiched between the word-line 40 and the second support substrate 34. The active isolation insulating film 30 is in contact with the bottom surface of the word-line 40 and the top surface of the second support substrate 34. Each of the isolation insulating films 36 is sandwiched between the word-line 40 and the second support substrate 34. Each of the isolation insulating films 36 is in contact with the bottom surface of the word-line 40, but is not in contact with the top surface of the second support substrate 34. The active isolation insulating film 30 has a greater depth than the isolation insulating film 36 in the Z-direction.

Through the above steps, the semiconductor device according to the first embodiment is formed. Thereafter, a peripheral circuit unit F and a capacitor unit G are connected in the same manner as in a second embodiment described later. As shown in FIGS. 11A, 11B and 11C, the active regions 32 are electrically isolated by the isolation insulating films 36 and the active isolation insulating films 30 in the semiconductor device according to the first embodiment. The active isolation insulating films 30 are formed by a process different from that of the isolation insulating films 36. The active isolation insulating films 30 are formed by forming the active isolation holes 28 from the back sides of the isolation insulating films 36 and filling the active isolation holes 28 with an insulating material.

The semiconductor device according to the embodiment makes it possible to reduce the planar area occupied by memory cells and peripheral circuits, thereby reducing the chip area of the semiconductor device. Therefore, it is possible to provide a semiconductor device which is reduced in cost.

A method of manufacturing a semiconductor device according to a second embodiment will be described below.

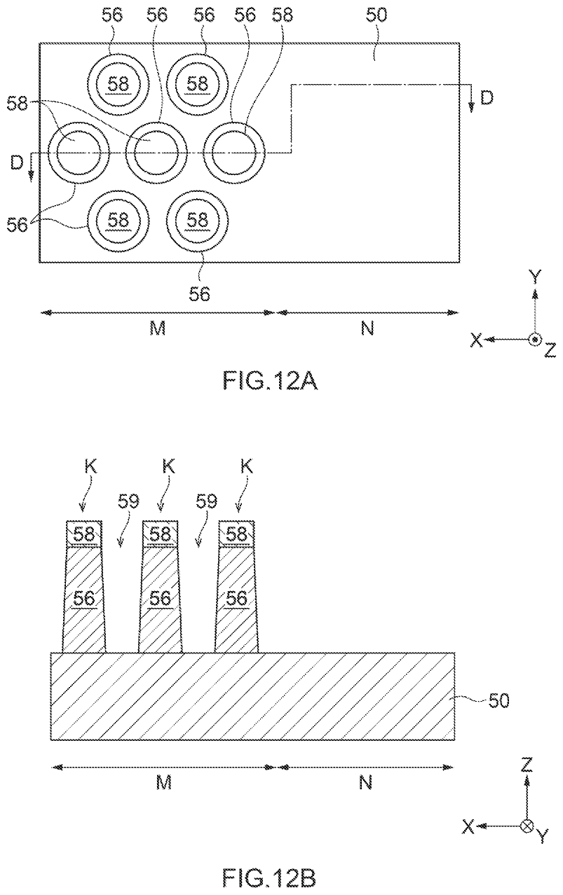

As shown in FIGS. 12A and 12B, a first semiconductor portion 56 and a first insulating portion 58 are laminated on a semiconductor substrate 50 to form films thereof. A memory cell region M and a peripheral circuit region N are provided on the semiconductor substrate 50.

The semiconductor substrate 50 includes, for example, a disk-shaped single-crystal silicon wafer having a mirror-finished principal surface.

The first semiconductor portion 56 contains, for example, silicon (Si). The first semiconductor portion 56 can be formed as a film, for example, by epitaxial growth. The first insulating portion 58 includes, for example, a silicon nitride film (SIN). The first insulating portion 58 can be formed as a film, for example, by CVD.

Next, the first insulating portion 58 and the first semiconductor portion 56 are patterned by using a known lithography technique and an anisotropic dry etching technique. This etching causes the surface of the semiconductor substrate 50 to be exposed. As a result, a plurality of pillar structures K extending in a direction vertical to the semiconductor substrate 50 and arranged independently of one another are formed. The pillar structures K are formed in the memory cell region M. The pillar structures K are formed on the semiconductor substrate 50, and the first semiconductor portion 56 and the first insulating portion 58 are laminated in each pillar structure K. A gap 59 is provided between the pillar structures K. Through the above steps, the structures shown in FIGS. 12A and 12B are formed.

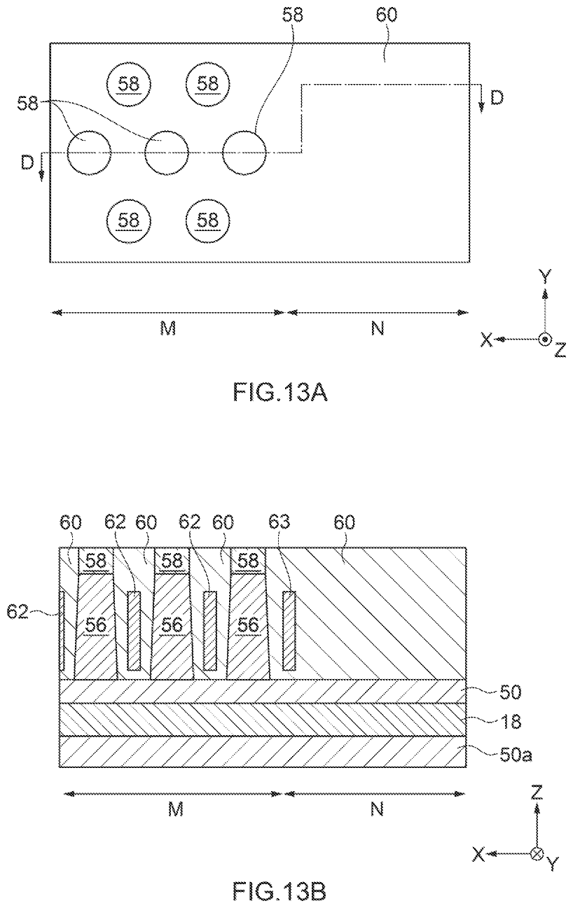

Next, as shown in FIGS. 13A and 13B, a first insulating film 60 and shield plates 62 are formed in the gaps 59 between the pillar structures K and in the peripheral circuit region N. A shield plate 63 is also formed near the boundary between the memory cell region M and the peripheral circuit region N. The shield plate 63 is formed around the memory cell region M. The first insulating film 60 contains an insulating material, for example, a silicon oxide film (SiO₂). The shield plates 62 and 63 contain a conductive material, for example, polysilicon (poly-Si) doped with phosphorus (P) as impurities. The first insulating film 60 and the shield plates 62 and 63 can be formed, for example, by film formation of a conductive material using a CVD method and performing etch back by anisotropic dry etching. Thereafter, an insulating film is formed to cover the shield plates 62 and 63 with the first insulating film 60.

Next, a hydrogen-implanted layer 18 is formed at a predetermined depth in the semiconductor substrate 50. Hydrogen (H) is introduced into the hydrogen-implanted layer 18. Hydrogen is formed, for example, by ion implantation of hydrogen ions (H⁺). The ion implantation is performed, for example, under the condition of an implantation energy of 50 Kev and an implantation dose of 1E16 atms/cm². The hydrogen-implanted layer 18 is formed at a position deeper than the first semiconductor portion 56. The hydrogen-implanted layer 18 is arranged between a lower semiconductor substrate 50a and the semiconductor substrate 50 above the lower semiconductor substrate 50a.

Here, the average projected range of hydrogen ions varies depending on the material through which the hydrogen ions pass. As shown in FIG. 13B, silicon (Si) contained in the first semiconductor portion 56 and the shield plates 62 is abundant in the memory cell region M. On the other hand, silicon dioxide (SiO₂) contained in the first insulating film 60 is abundant in the peripheral circuit region N. The average projected range of hydrogen ions is shorter in the case where hydrogen ions pass through silicon. Therefore, the average projected range of hydrogen ions to be implanted into the memory cell region M and the average projected range of hydrogen ions to be implanted into the peripheral circuit region N may differ. Therefore, in order to match the average projected ranges of hydrogen ions in the memory cell region M and the peripheral circuit region N, an adjustment portion for the average projected range which contains, for example, silicon dioxide or amorphous carbon having a predetermined film thickness may be provided on the peripheral circuit region N.

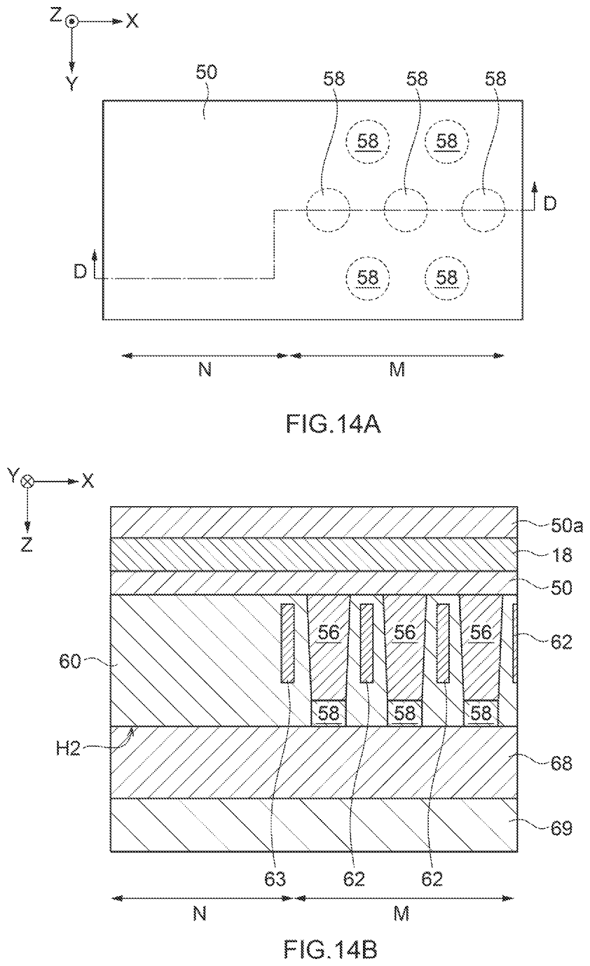

Next, as shown in FIGS. 14A and 14B, the semiconductor substrate 50 is rotated such that the X-axis is rotated around the Y-axis by 180 degrees. Next, the semiconductor substrate 50 is bonded at a bonding surface H2 to a first support substrate 69 on which a third insulating film 68 has been formed in advance, by the wafer bonding technique. At the bonding surface H2, the surfaces of the first insulating film 60 and the first insulating portions 58 are in contact with the surface of the third insulating film 68.

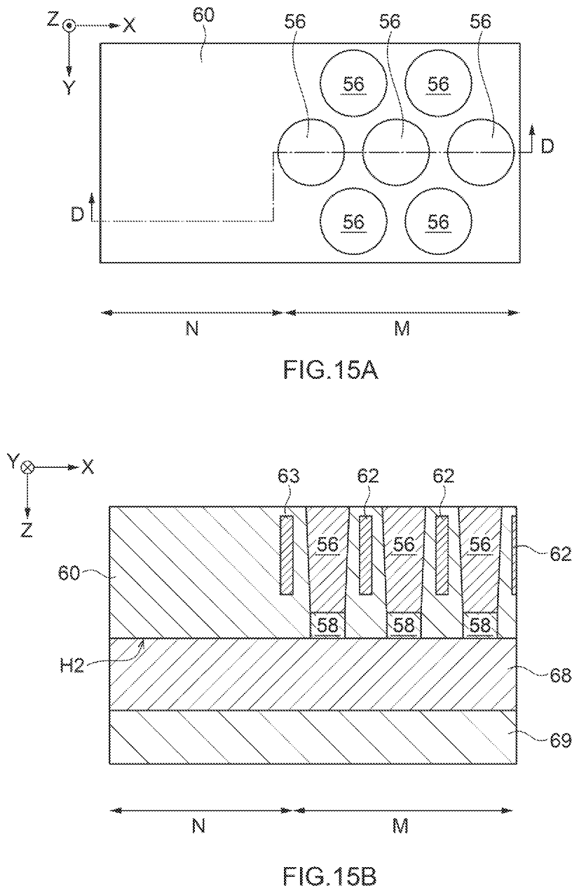

Next, as shown in FIGS. 15A and 15B, the smart cut technique is performed on the first support substrate 69 on which the pillar structures K and the shield plates 62 and 63 are formed. Specifically, an annealing treatment is performed at a temperature of 400 to 500° C. in an N2 atmosphere. As a result, the hydrogen-implanted layer 18 expands, so that the hydrogen-implanted layer 18 and the lower semiconductor substrate 50a are peeled off. As described above, in the second embodiment, hydrogen ions are implanted into the first support substrate 69 on which patterned structures such as the pillar structures K and the shield plates 62 and 63 have been formed, and then the smart cut technique is performed.

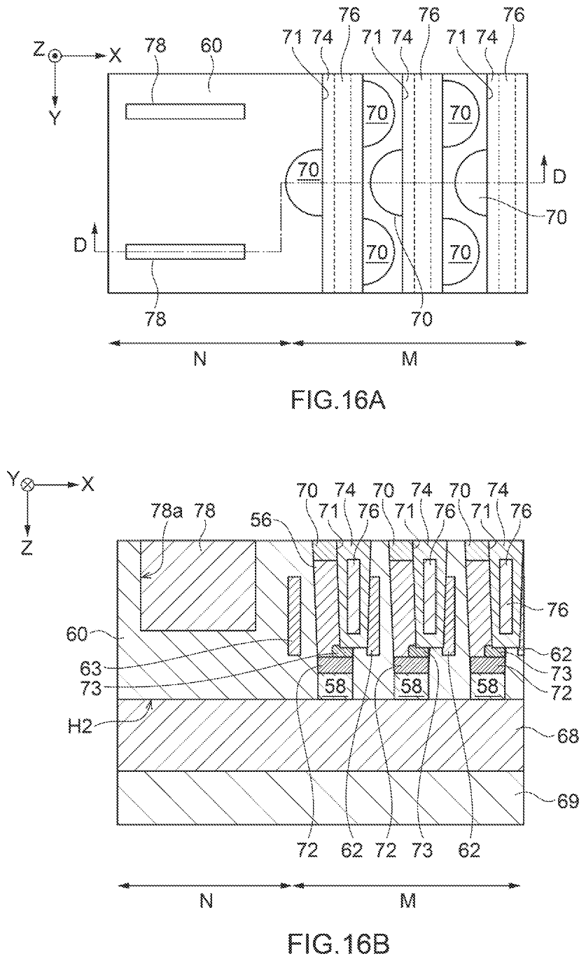

Next, a step of forming a structure shown in FIGS. 16A and 16B will be described. A first doped layer 70 is formed at an upper portion of the first semiconductor portion 56 in the figure. The first doped layer 70 is formed, for example, by performing the ion implantation technique. The first doped layer 70 contains, for example, phosphorus (P) as impurities. Next, trenches 71 extending in the Y-direction in the figures are formed in a part of the first semiconductor portions 56 and the first insulating film 60. The trenches 71 are formed, for example, by using the known lithography technique and the anisotropic dry etching technique. The anisotropic dry etching is performed under the condition that the etching rates of the first semiconductor portion 56 and the first insulating film 60 are substantially equal to each other. The bottom portions of the trenches 71 are controlled to be positioned above the lower surfaces of the first semiconductor portions 56.

Next, for example, impurities, at least one of phosphorus or arsenic, are implanted into the first semiconductor portions 56 located at the bottom portions of the trenches 71 by ion implantation, and then a heat treatment is performed to activate the impurities. The heat treatment is performed at a temperature of 1050° C. in an inert gas atmosphere such as nitrogen, for example, by using a lamp annealing apparatus. As a result, the impurities doped in a first doped layer 70, a second doped layer 72 and a third doped layer 73 are activated. In the formation of the second doped layer 72 and the third doped layer 73, ion implantation is performed by using different implantation energies.

The first doped layer 70, the second doped layer 72, and the third doped layer 73 function as a source/drain region of an access transistor 142 which is a vertical transistor described later. The first semiconductor portion 56 functions as a channel region of the access transistor 142. The third doped layer 73 functions as an extension portion of the source/drain region of the access transistor 142.

The first semiconductor portion 56 functions as a channel region of the access transistor 142. The access transistor 142 functions as a full depletion type or partial depletion type SOI transistor. The shield plates 62 and 63 are connected to a predetermined potential, and function as an isolation for electrically isolating the access transistor 142.

In DRAM, the source and drain of an access transistor are interchanged between data writing and reading operations, and thus a pair of source and drain regions of a transistor is herein described as a source/drain region.

Next, a gate insulating film 74 and a gate electrode 76 are formed inside the trench 71. The gate insulating film 74 contains, for example, silicon dioxide. The gate electrode 76 contains a conductive material, for example, titanium nitride. In the longitudinal sectional view of FIG. 16B, the gate electrode 76 is surrounded by the gate insulating film 74. The gate insulating film 74 and the gate electrode 76 are formed by forming silicon dioxide and titanium nitride in the trench 71, for example, by the CVD method, performing etch back by anisotropic dry etching, and then filling a recess formed on the gate electrode 76 by etching back with silicon dioxide. In this way, the gate electrode 76 is formed so as to face and contact, via the gate insulating film 74, the side surface of the first semiconductor portion 56 which is a channel region.

In the same process steps as the formation of the trenches 71 and the gate electrodes 76, trenches 78a and pull-out-electrodes 78 are formed. The pull-out-electrodes 78 are formed of the same material as the gate electrodes 76. The same insulating film as the gate insulating film 74 formed in the trench 71 is also formed on the side surface of the trench 78a. However, since the insulating film is integrated with the first insulating film 60, it is omitted from FIG. 16B and the like. The pull-out-electrodes 78 are formed by forming silicon dioxide and titanium nitride in the trenches 78a, for example, by the CVD method and performing etch back by anisotropic dry etching in the same process steps as the formation of the gate electrodes 76.

Here, etch back is performed in a state where a patterned resist (not shown) is formed on the pull-out-electrodes 78. The resist is patterned by the known lithography technique. Additional etch back may be performed after removing the resist. In this way, the upper surfaces of the pull-out-electrodes 78 are adjusted to be higher than the upper surfaces of the gate electrodes 76. Further, by this etch back, the height from the top surface of the first support substrate 69 to the top surfaces of the first doped layers 70 and the height from the top surface of the first support substrate 69 to the top surfaces of the pull-out-electrodes 78 are adjusted to be substantially equal to each other in FIG. 16B.

Further, recesses are formed above the gate electrodes 76 by this etch back. Thereafter, silicon dioxide is filled in the recesses formed above the gate electrodes 76. A structure in which the upper portions of the gate electrodes 76 are covered with the insulating film and the top surfaces of the pull-out-electrodes 78 are exposed is formed through the above steps. The structure shown in FIGS. 16A and 16B is formed through the above steps.

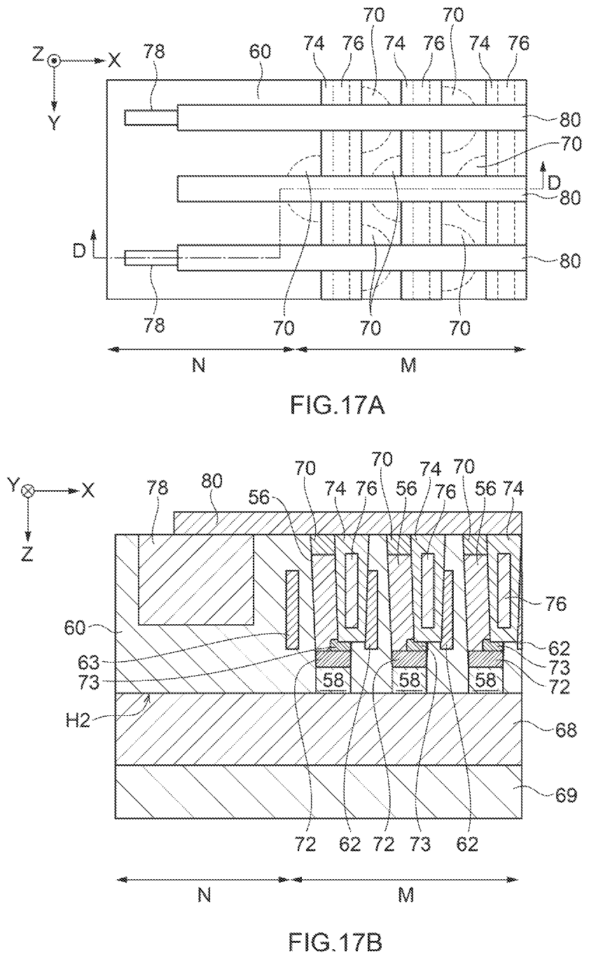

Next, as shown in FIGS. 17A and 17B, a plurality of bit-lines 80 extending in the X-direction are formed. The bit-lines 80 contain a conductive material, for example, any one of tungsten silicide (WSi), tungsten nitride (WN), and tungsten (W). The bit-lines 80 are in contact with the first doped layers 70 and the pull-out-electrodes 78, and are electrically connected to the first doped layers 70 and the pull-out-electrodes 78. The bit-lines 80 are formed, for example, by performing the known lithography technique and the anisotropic dry etching technique on a conductive film formed by CVD.

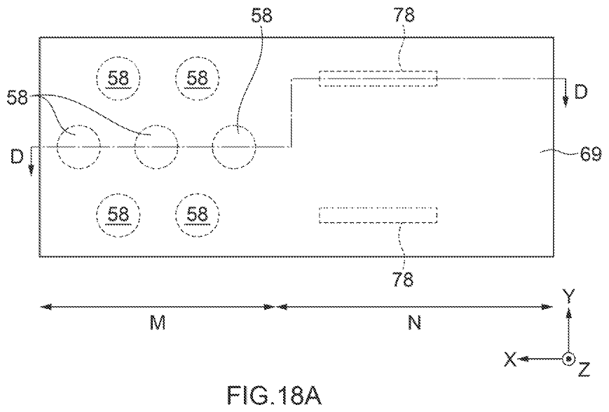

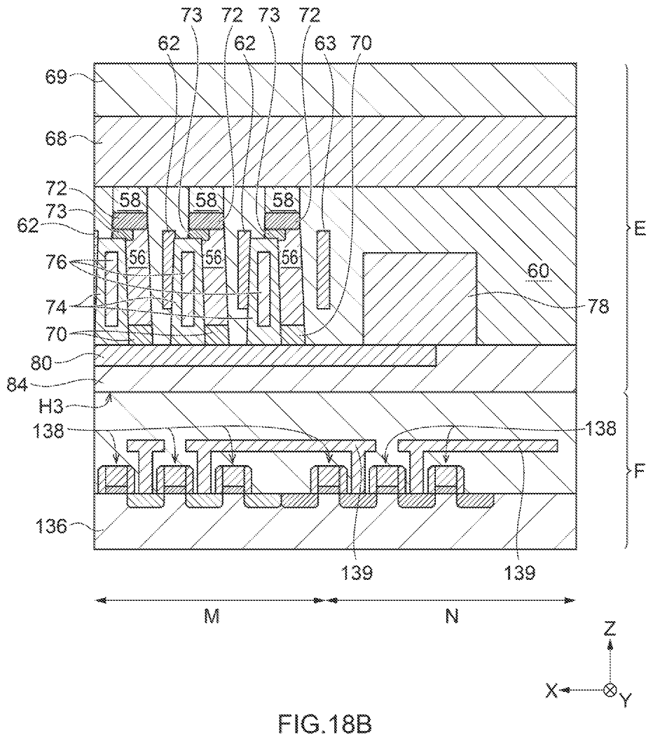

Next, the steps of forming a structure shown in FIGS. 18A and 18B will be described. An on-bit-line insulating film 84 is formed on the bit-line 80. The on-bit-line insulating film 84 contains an insulating material, for example, silicon nitride. The on-bit-line insulating film 84 is formed, for example, by CVD. A structure formed through the above steps, that is, a structure including the first support substrate 69, the third insulating film 68, the first insulating portions 58, the first semiconductor portions 56, the first doped layers 70, the second doped layers 72, and the third doped layers 73, the gate insulating films 74, the gate electrodes 76, the pull-out-electrodes 78, the bit-lines 80, and the on-bit-line insulating films 84 is called a memory cell portion E.

Next, the memory cell portion E is rotated such that the X-axis is rotated around the Y-axis by 180 degrees. Next, a peripheral circuit portion F including a second semiconductor substrate 136, peripheral circuit transistors 138, wirings 139, and the like is prepared. In the peripheral circuit portion F, the peripheral circuit transistors 138, the wirings 139 and the like are formed on the second semiconductor substrate 136 in advance. A heat treatment for activation of impurities doped in the source/drain of each of the peripheral circuit transistors 138 is performed before bonding using the wafer bonding technique. The memory cell portion E and the peripheral circuit portion F are bonded to each other by the wafer bonding technique. In the wafer bonding technique, for example, a fusion bonding method can be used. The memory cell portion E and the peripheral circuit portion F are bonded to each other at a bonding surface H3. Through the above steps, the structure shown in FIGS. 18A and 18B is formed.

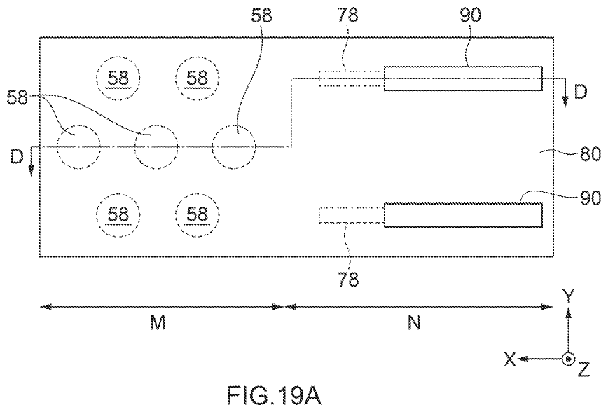

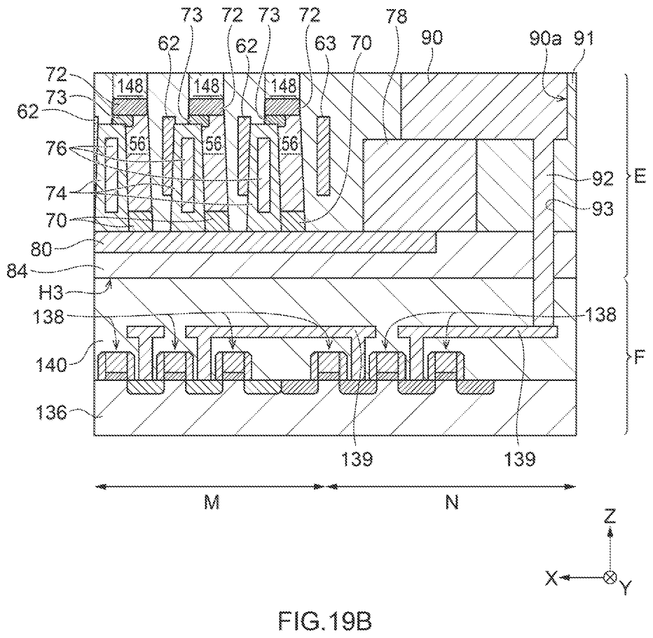

Next, as shown in FIGS. 19A and 19B, the first support substrate 69 and the third insulating film 68 are removed. The first support substrate 69 and the third insulating film 68 can be removed, for example, by CMP, etching or the like. The first support substrate 69 and the third insulating film 68 are removed, so that the surface of the first insulating film 60 and the surfaces of the first insulating portions 58 are exposed. The memory cell portion E has a structure in which the first support substrate 69 and the third insulating film 68 are removed.

Next, the first insulating portions 58 are selectively removed. The first insulating portions 58 are selectively removed by etching using, for example, a hot phosphoric acid solution. Recesses are formed at places where the first insulating portions 58 have been removed, so that the top surfaces of the second doped layers 72 are exposed.

Next, by performing a known lithography method and anisotropic dry etching, trenches 90a reaching the surfaces of the pull-out-electrodes 78 from the surface of the first insulating film 60 are formed in the peripheral circuit region N. The trenches 90a are formed by performing the known lithography method and the anisotropic dry etching. Next, contact holes 93 reaching the wirings 139 of the peripheral circuit section F are

formed. The contact holes 93 are formed by performing the known lithography method and the anisotropic dry etching. The order of forming the trenches 90a and the contact holes 93 can be reversed. Next, the recesses formed by removing the first insulating portions 58, the contact holes 93 and the trenches 90a are filled with a conductive material, thereby forming conductive portions 148, contact electrodes 92, and pull-out-electrodes 90. The filling of the conductive material is performed by forming a conductive material film, for example, by CVD, and performing anisotropic dry etching to etch back until the top surface of the first insulating film 60 is exposed. The conductive portions 148, the contact electrodes 92, and the pull-out-electrodes 90 contain a conductive material, for example, tungsten. The conductive portions 148, the contact electrodes 92 and the pull-out-electrodes 90 are formed, for example, by CVD. A plane including the top surfaces of the first insulating film 60, the conductive portions 148, and the pull-out-electrodes 90 is formed.

An example in which the pull-out-electrodes 90 and the contact electrodes 92 are formed by using a so-called dual damascene technique is herein shown, but they may be formed by using a single damascene technique. In this way, the bit-lines 80 are electrically connected to the pull-out-electrodes 78, the pull-out-electrodes 90, the contact electrodes 92, and the wirings 139. Through the above steps, the structure shown in FIGS. 19A and 19B is formed.

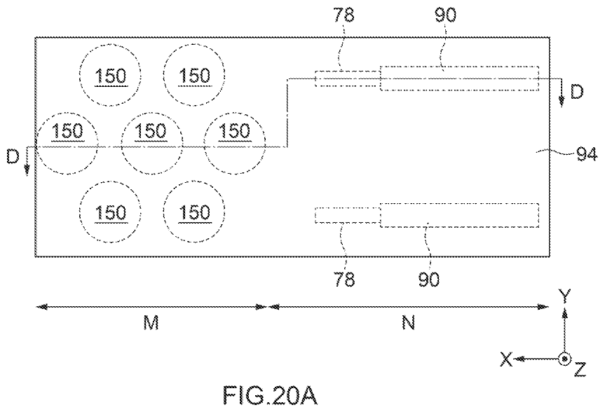

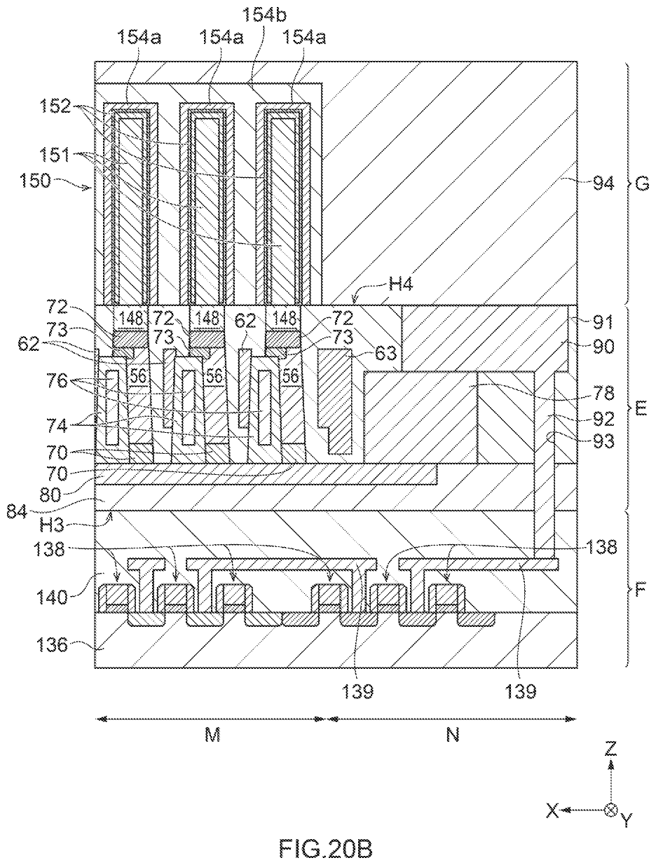

Next, as shown in FIGS. 20A and 20B, a capacitor portion G in which a storage capacitor 150 is formed in advance and the memory cell portion E are bonded to each other at a bonding surface H4 by the wafer bonding technique. In the wafer bonding technique, for example, a fusion bonding method can be used. The top surface of the memory cell portion E and the bottom surface of the capacitor portion G are in contact with each other at the bonding surface H4. The capacitor portion G includes the storage capacitor 150. The storage capacitor 150 includes first electrodes 151, capacitive insulating films 152, second electrodes 154a and a third electrode 154b.

The capacitive insulating film 152 contains, for example, a high-k film having a high relative dielectric constant, and contains, for example, metal oxide such as hafnium oxide (HfO₂), zirconium oxide (ZrO₂), or aluminum oxide (Al₂O₃). The capacitive insulating films 152 are formed, for example, by CVD. The first electrodes 151 and the second electrodes 154a contain a conductive material, for example, titanium nitride (TiN). The first electrodes 151 and the second electrodes 154a are formed, for example, by CVD. The capacitive insulating film 152 is sandwiched between the first electrode 151 and the second electrode 154a. The capacitive insulating film 152, the first electrode 151, and the second electrode 154a function as a capacitor, and can store and release charges. The first electrode 151 is in contact with the conductive portion 148. The second electrode 154a is connected to a plate electrode (not shown). The third electrode 154b covers the second electrodes 154a. The third electrode 154b contains a conductive material, for example, tungsten. The third electrode 154b is formed, for example, by CVD, and patterned using the known lithography technique and the anisotropic dry etching technique. The storage capacitor 150 and the third electrode 154b that covers the storage capacitor 150 are covered by a fifth insulating film 94.

Through the above steps, a memory cell array including the bit-lines 80, the gate electrodes 76, the access transistors 142, and the storage capacitors 150 is formed. The access transistors 142 are provided in the active regions 32 and the first semiconductor portions 56 described above.

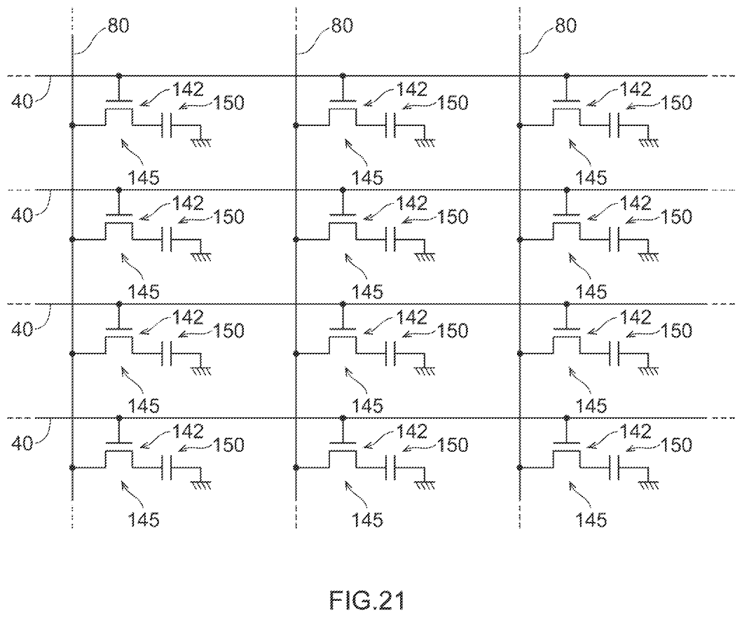

FIG. 21 shows an equivalent circuit of the memory cell array of the semiconductor devices according to the first and second embodiments. A plurality of memory cells 145 are arranged in a matrix form while the memory cells 145 are connected to respective intersections between pluralities of word-lines 40 and bit-lines 80 which are arranged orthogonally. One memory cell 145 includes a pair of the access transistor 142 and the storage capacitor 150.

The access transistor 142 includes, for example, a MOSFET. The gate electrode of the access transistor 142 functions as a word-line 40 of the DRAM. The word-line 40 functions as a control line for controlling selection of corresponding memory cells. One of the source/drain of the access transistor 142 is connected to the bit-line 80, and the other is connected to the storage capacitor 150. The storage capacitor 150 includes a capacitor, and data is stored by accumulating charges in the capacitor.

When writing data into the memory cell 145, a potential for setting the access transistor 142 to ON is applied to the word-line 40, and a low potential or a high potential corresponding to write data “0” or “1” is applied to the bit-line 80. When reading data from the memory cell 145, a potential for setting the access transistor 142 to ON is applied to the word-line 40. As a result, a potential drawn from the storage capacitor 150 to the bit-line 80 is sensed by a sense amplifier connected to the bit-line 80, thereby determining the data.

Through the above steps, it is possible to achieve a structure in which the access transistor 142 and the storage capacitor 150 are vertically stacked in the Z direction. By implementing such an arrangement as described above, the area occupied by the memory cells on the X-Y plane can be reduced, so that a highly integrated semiconductor device can be achieved.

As described above, the semiconductor devices according to the embodiments have been described by illustrating DRAM, but these are examples and there is no intention to limit the semiconductor device to DRAM. With respect to the semiconductor devices, the embodiments are applicable to memory devices other than DRAM, for example, a static random access memory (SRAM), a flash memory, an erasable programmable read only memory (EPROM), a magnetoresistive random access memory (MRAM), a phase-change memory and the like. Further, with respect to the semiconductor devices according to the above embodiments, the embodiments are applicable to devices other than memories, for example, a microprocessor, a logic IC such as an application specific integrated circuit (ASIC), and the like.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first semiconductor substrate;
a plurality of first regions extending in parallel in a first direction on the first semiconductor substrate, each of the plurality of first regions including a plurality of first shallow trench isolations (STI) therein; and
a plurality of second regions each extending between corresponding adjacent two of the plurality of first regions, each of the plurality of second regions including a plurality of second STIs and a plurality of active regions arranged alternately and in line in the first direction;
wherein each of the plurality of second STIs has a greater depth than each of the plurality of first STIs.

2. The apparatus of claim 1, further comprising a plurality of word-lines extending in a second direction crossing the first direction above the first semiconductor substrate.

3. The apparatus of claim 2, further comprising an insulating film and a second semiconductor substrate provided on a back surface of the first semiconductor substrate, and
wherein each of the plurality of second STIs is sandwiched between a corresponding one of the plurality of word-lines and the first semiconductor substrate.

4. The apparatus of claim 1, wherein the plurality of first STIs and the plurality of second STIs comprise a same material.

5. The apparatus of claim 4, wherein the same material comprises silicon dioxide.

6. The apparatus of claim 2, wherein each of the plurality of active regions is crossed by corresponding two of the plurality of word-lines such that each of the plurality of active regions comprises two transistors.

7. The apparatus of claim 2, wherein the plurality of word-lines comprise conductive material.

8. The apparatus of claim 2, wherein the plurality of word-lines comprise titanium nitride.

9. A method comprising:
implanting hydrogen ions into a substrate to form a lower substrate layer, a hydrogen-implanted layer on the lower substrate layer and an upper substrate layer on the hydrogen-implanted layer; and
annealing the substrate after implanting hydrogen ions to peel away the hydrogen-implanted layer and the lower substrate layer together from the substrate.

10. The method of claim 9, wherein the annealing expands the hydrogen-implanted layer.

11. The method of claim 9, wherein the substrate includes a structure including isolation.

12. The method of claim 9, wherein the substrate comprises a silicon monocrystalline substrate.

13. The method of claim 9, wherein the annealing is performed in N2 atmosphere at a temperature of 400° C. to 500° C. for about 30 minutes.

14. A method comprising:
forming a plurality of isolation structures in a substrate;
implanting hydrogen ions into a substrate to form a lower substrate layer, a hydrogen-implanted layer on the lower substrate layer and an upper substrate layer on the hydrogen-implanted layer, the upper substrate layer including the plurality of isolation structures; and
annealing the substrate after implanting hydrogen ions to peel away the hydrogen-implanted layer and the lower substrate layer together from the substrate.

15. The method of claim 14, wherein forming the isolation comprises:
dry etching to form a trench in the substrate; and
chemical vapor deposition to fill the trench with an insulating material.

16. The method of claim 14, wherein forming the isolation comprises:
dry etching to form a trench in the substrate; and
filling the trench with a conductor and an insulator surrounding the conductor.

17. The method of claim 14, further comprising forming transistor elements on the substrate.

18. The method of claim 17, wherein forming transistor elements comprises:
etching the substrate to form trenches, and
filling the trenches with a conductive material.

19. The method of claim 14, wherein the annealing is performed in N2 atmosphere at a temperature of 400° C. to 500° C. for about 30 minutes.

20. The method of claim 14, wherein the annealing expands the hydrogen-implanted layer.
